(19) United States
(12) Patent Application Publication
(10) Pub. No.: US 2011/0132455 A1
(43) Pub. Date: Jun. 9, 2011

(54) SOLAR CELL WITH LUMINESCENT MEMBER

(75) Inventors: Huo-Hsien Chiang, Taipei City (TW); Chiou-Fu Wang, Yonghe City (TW)

(73) Assignee: Du Pont Apollo Limited, Pak Shek Kok (HK)

(21) Appl. No.: 12/959,046

(22) Filed: Dec. 2, 2010

Related U.S. Application Data
(60) Provisional application No. 61/266,505, filed on Dec. 3, 2009.

(51) Int. Cl. H01L 31/0232

(52) U.S. Cl. 136/257

(57) ABSTRACT

Disclosed herein is a solar cell, which includes a transparent substrate, an optical layer, a luminescent member and a photovoltaic device. The optical layer is disposed on the transparent substrate, and is capable of reflecting light having wavelengths in the range of about 500 nm to about 730 nm, and also transmitting light having wavelengths in the range of about 300 nm to about 600 nm. The luminescent member is disposed on the optical layer, and is capable of emitting a light having wavelengths in the range of about 500 nm to about 730 nm. The photovoltaic device is disposed on the luminescent member and is operable to convert light into electricity.

### RELATED APPLICATIONS

This application claims priority to U.S. Provisional Application Ser. No. 61/266,505, filed Dec. 3, 2009, which is herein incorporated by reference.

### BACKGROUND

1. Field of Invention

The present invention relates to a photovoltaic device. More particularly, the present invention relates to a solar cell with a luminescent member.

2. Description of Related Art

Solar energy has gained many research attentions for being a seemingly inexhaustible energy source. For such purpose, solar cells that convert solar energy directly into electrical energy are developed.

Currently, solar cells are often made of single crystalline silicon or poly crystalline silicon, and such devices account for more than 90% of the solar cell market. However, production of these types of solar cells would require high quality silicon wafers, thereby rendering the manufacturing process cost in-effective. Furthermore, silicon wafer-based solar cells are not suitable for certain applications such as transparent glass curtain and other building integrated photovoltaics (BIPV). Therefore, thin film solar cells, particularly, see-through type thin film solar cells, are employed in the aforementioned application.

A conventional see-through type thin film solar cell module includes a glass substrate, a transparent electrode, a photoelectric conversion layer and a back contact. The transparent electrode is formed on the glass substrate. The photoelectric conversion layer is disposed on the transparent electrode. Moreover, the back contact is disposed on the photoelectric conversion layer by position displacement, and is in contact with the underlying transparent electrode. In order to increase the efficiency of the solar cell, pyramid-like structures or textured structures are formed on the surface of the transparent conductive layer. However, these pyramid-like or textured structures increase the efficiency of the solar cell only marginally for light may directly pass through the photoelectric conversion layer and transmits out of the solar cell without being absorbed therein.

Therefore, there exists in this art a need of improved solar cells having higher photoelectric conversion efficiency.

### SUMMARY

The present disclosure provides a solar cell, which includes a transparent substrate, an optical layer, a luminescent member and a photovoltaic device. The optical layer is disposed on the transparent substrate, and may reflect light having a wavelength in the range between about 500 nm and about 730 nm, and transmits light having a wavelength in the range between about 300 nm and about 600 nm. The luminescent member is disposed on the optical layer, and is operable to emit a light having a wavelength in the range between about 500 nm and about 730 nm. Furthermore, the photovoltaic device capable of converting light into electricity is disposed on the luminescent member.

According to one embodiment of the present disclosure, the luminescent member may comprise a luminescent material having a maximal spectra intensity in the range between about 500 nm and about 700 nm.

According to another embodiment of the present disclosure, the luminescent material includes, but is not limited to, 4-(dicyanomethylene)-2-t-butyl-6-(1,1,7,7-tetramethyljulolidyl-9-enyl)-4H-pyran (DCJTB), oxazine-4-perchlorate, 3-phenyl-fluoranthene, GF ORANGE-RED™, GF CLEAR™, FLUOROL 555™, LDS 730™, LDS 750™, BASF 241™ and BASF 339™.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view of one embodiment of the present disclosure;

FIG. 2A and FIG. 2B respectively illustrate the reflectance and the transmittance of an optical layer according to one embodiment of the present disclosure;

FIG. 2C illustrates a cross-sectional view of an optical layer according to one embodiment of the present disclosure;

FIG. 2D illustrates the emitting spectrum of a luminescent member according to one embodiment of the present disclosure;

FIG. 3A and FIG. 3B respectively illustrate the reflectance and the transmittance of an optical layer according to another embodiment of the present disclosure; and

FIG. 3C illustrates the emitting spectrum of a luminescent member according to another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

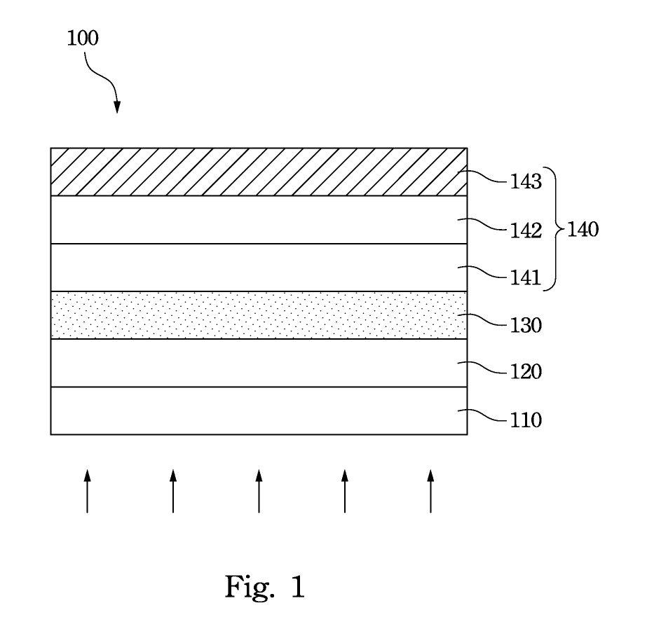

FIG. 1 is a cross-sectional view of a solar cell according to one embodiment of the present disclosure. As depicted in FIG. 1, the solar cell 100 includes a transparent substrate 110, an optical layer 120, a luminescent member 130, and a photovoltaic device 140. The photovoltaic member 200 is capable of converting light into electricity, and is described in detail hereinafter.

In general, sunlight projects on the solar cell 100 from the side of the transparent substrate 110. The material of the transparent substrate 110 is non-limited, so long as it is stable in the ambient environment and is transparent to sunlight. For example, the transparent substrate 110 may be made of glass or other transparent plastics such as Poly(methyl methacrylate) (PMMA), polystyrene and polycarbonate. The transparent substrate 110 may protect the optical layer 120, the luminescent member 130 and the photovoltaic device 140 from damage, and may further prevent mist and pollutions from leaking into the solar cell 100.

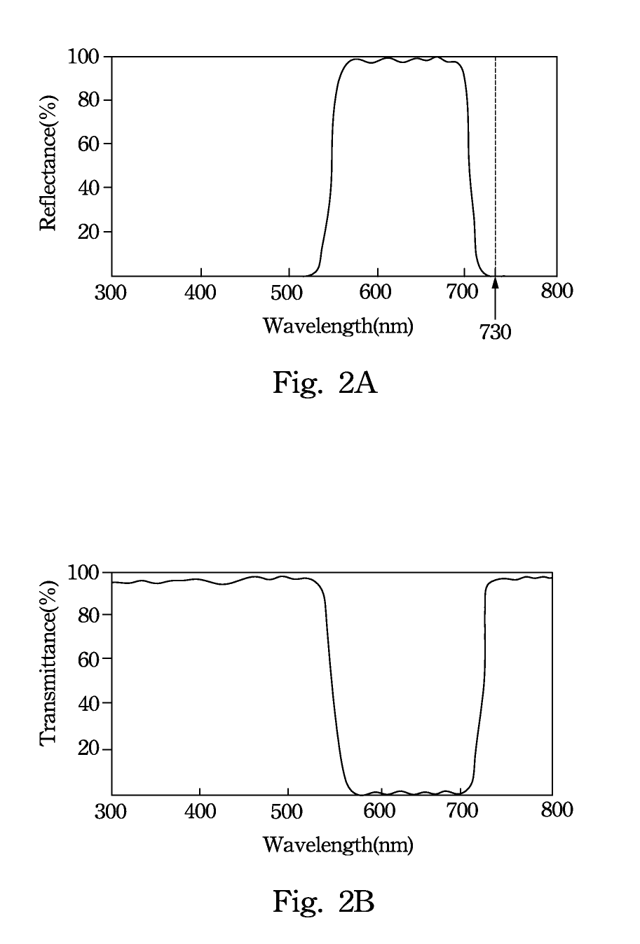

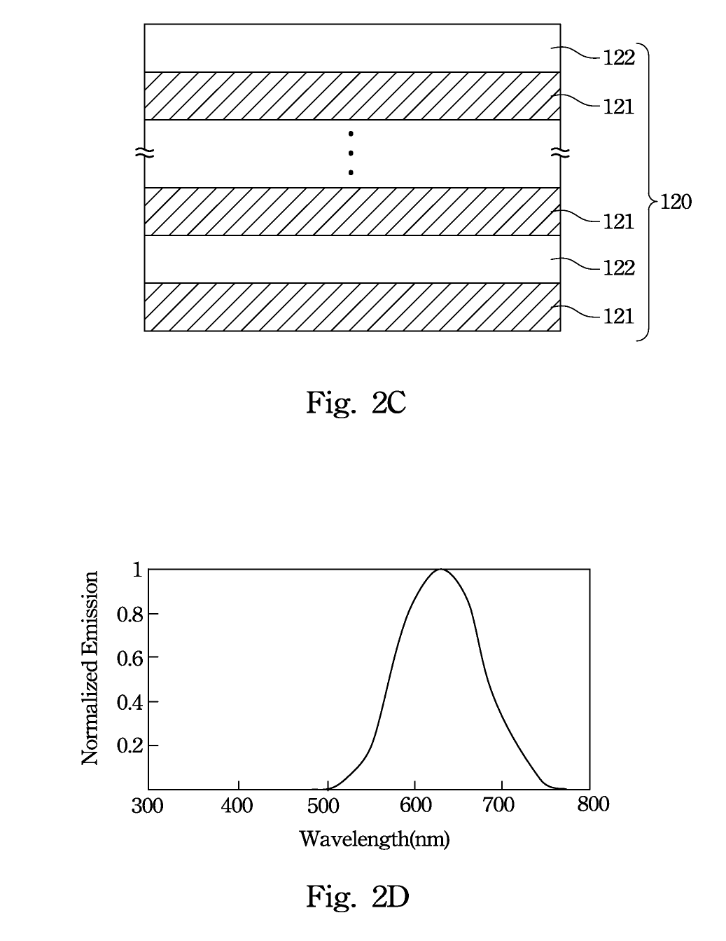

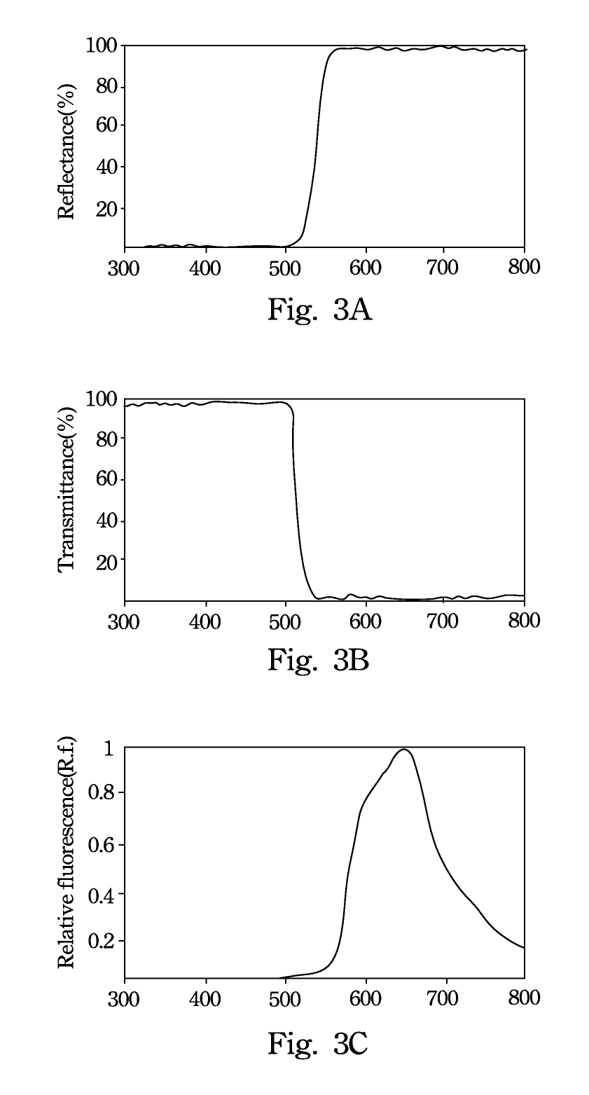

The optical layer 120 is disposed on the transparent substrate 110. The optical layer 120 is capable of reflecting light having a wavelength in the range between about 500 nm and about 730 nm, and transmitting light having wavelengths in the range between about 300 nm and about 600 nm. In one embodiment, more than 90% of the light having a wavelength in the range between about 500 nm and about 730 nm may be reflected by the optical layer 120, and more than 90% of the light having a wavelength in the range between about 300 nm and about 600 nm may be transmitted through the optical layer 120. In one example, as depicted in FIG. 2A and FIG. 2B, the optical layer 120 may have a reflectance of over 90% from about 550 nm to about 700 nm, and a transmittance of over 90% from about 300 nm to about 540 nm. In another example, as shown in FIG. 3A and FIG. 3B, the optical layer 120 has a high reflectance, for example about 95%, for the light in the range from about 550 nm to 800 nm, and a high transmittance of about 95% for the light in the range from about 300 nm to about 510 nm. The above mentioned optical properties of the optical layer 120 may be designed and accomplished by the theory of thin-film interference, and is described in the following paragraph.

FIG. 2C illustrates the structure of the optical layer 120 according to one embodiment of the present disclosure. The optical layer 120 may comprise a plurality of first layers 121 and a plurality of second layers 122, in which each of the first and second layers 121, 122 are alternately arranged. In another embodiment, the first and second layers 121, 122 respectively have a first refractive index and a second refractive index, and the first refractive index is larger than the second refractive index. For example, the first layer 121 having a high refractive index may be made of titanium dioxide, and the second layer 122 may be made of silica. The reflectance and the transmittance of the optical layer 120 may be modified by adjusting the thicknesses of the first and second layers, and by the number of the first and second layers according to the desired absorption spectra of the photoelectric conversion layer in photovoltaic device. Further, the materials of the first and second layers may affect the reflectance and the transmittance of the optical layer 120.

The luminescent member 130 is disposed on the optical layer 120, which is to absorb the light transmitted through the optical layer 120, such that the luminescent member 130 emits a light having a wavelength within the absorption spectra of the photoelectric conversion layer in the photovoltaic device. For example, the luminescent member 130 is capable of emitting a light having a wavelength in the range between about 500 nm and about 730 nm by absorbing a light having a wavelength in the range between about 300 nm and about 600 nm. Typically, the luminescent member 130 may absorb a light having a higher energy, and emits a light having a lower energy. Moreover, the luminescent member 130 has absorption spectra and emission spectra, wherein edge of the emission spectra of the luminescent member 130 is below the edge of absorption spectra of the photoelectric conversion layer in the photovoltaic device 140. This means that a material of the luminescent member 130 is determined by the desired absorption spectra of the photoelectric conversion layer in photovoltaic device 140.

In one embodiment, the luminescent member 130 comprises a layer of luminescent material that emits a light having a maximal spectral intensity in the range between about 500 nm and about 700 nm. In one example, the luminescent material may be an organic dye molecular, for example 4-(dicyanomethylene)-2-t-butyl-6-(1,1,7,7-tetramethyljulolidyl-9-enyl)-4H-pyran (DCJTB), and is formed on the optical layer 120 by thermal evaporation, though conventional solution coating processes such as die coating and spin coating may be employed as well. In another embodiment, the luminescent member 130 is made of a luminescent material which includes, but is not limited to, 4-(dicyanomethylene)-2-t-butyl-6-(1,1,7,7-tetramethyljulolidyl-9-enyl)-4H-pyran (DCJTB), oxazine-4-perchlorate, 3-phenyl-fluoranthene, GF ORANGE-RED™, GF CLEAR™, FLUOROL 555™, LDS 730™, LDS 750™, BASF 241™ and BASF 339™. GF ORANGE-RED™ and GF CLEAR™ are available from Ciba-Geigy-Ten-Horn-Pigment Chemie N. V. Holland; FLUOROL 555™, LDS 730™ and LDS 750™ are available from Exciton Chemical Co. Inc., Dayton, Ohio, and BASF 241™ and BASF 339™ are available from BASF Aktiengeselschaft, Germany.

The luminescent member 130 may comprise one or more luminescent materials described above. In one example, the luminescent member 130 comprises a layer of DCJTB with its emitting spectrum depicted in FIG. 2D. The emitting spectrum spans across a wavelength range from about 520 nm to about 750 nm and a maximal emission intensity occurs at about 630 nm. In another example, the luminescent member 130 may include a layer of BASF 339™, a layer of BASF 241™ and a layer of GF CLEAR™ in sequence, wherein the layer of BASF 339™ is disposed on the optical layer 120. FIG. 3C illustrates the emitting spectrum of the luminescent member 130 having three layers.

In still another embodiment, the luminescent member 130 may comprise a matrix and a luminescent material dispersed therein. In one example, the matrix comprises tris(8-hydroxyquinoline) aluminum (AlQ₃), and the luminescent material includes, but is not limited to 4-(dicyanomethylene)-2-t-butyl-6-(1,1,7,7-tetramethyljulolidyl-9-enyl)-4H-pyran (DCJTB), oxazine-4-perchlorate, 3-phenyl-fluoranthene, GF ORANGE-RED™, GF CLEAR™, FLUOROL 555™, LDS 730™, LDS 750™, BASF 241™ and BASF 339™. In one example, DCJTB is doped in the AlQ₃ by physical deposition process, though other solution process may be used as well. In this example, AlQ₃ forms a stable amorphous film, and the resulting AlQ3:DCJTB film was about 6 μm in thickness.

Light within the transmissible region of the optical layer 120, for example from 300 nm to 600 nm, may be transmitted through the optical layer 120 and reach the luminescent member 130. The luminescent member 130 then absorbs the incident light emitted from the optical layer 120 and converts it into a light having a longer wavelength that could be absorbed by the photoelectric conversion layer of the photovoltaic device, for example in the range between about 500 nm and about 730 nm. Moreover, part of the light, emitted from the luminescent member 130 but hasn't been absorbed by the photoelectric conversion layer yet, may substantially be reflected by the optical layer 120 and back conductive layer, rather than be transmitted out of the optical layer 120. Thus, the light is trapped in the solar cell 100, and thereby photoelectric conversion efficiency is improved.

The photovoltaic device 140 is disposed on the luminescent member 130. In one embodiment, the photovoltaic device 140 includes a transparent conductive layer 141, a photoelectric conversion layer 142 and a back conductive layer 143.

The transparent conductive layer 141 is disposed on the luminescent member 130. In one example, the transparent conductive layer 141 is a transparent conductive oxide layer. For example, the transparent conductive oxide layer may include zinc oxide (ZnO), fluorine doped tin dioxide (SnO₂:F), or indium tin oxide (ITO).

The photoelectric conversion layer 142 is disposed on the transparent conductive layer 141. In some examples, the photoelectric conversion layer 142 includes a p-i-n structure composed of a p-type semiconductor, an intrinsic semiconductor and an n-type semiconductor (not shown). The intrinsic semiconductor, also called an undoped semiconductor, is a pure semiconductor without any significant amount of dopant species present therein. In these examples, the material of these semiconductors may include but not limited to amorphous silicon. The amorphous silicon may absorb a light having a wavelength less than about 730 nm. Alternatively, the photoelectric conversion layer 142 may be of any type such as those made from crystalline silicon, GaAs, ClGS, or CdTe according to the demands. When the photoelectric conversion layer 142 absorbs light, electron-hole pairs are generated therein, and then the electron-hole pairs are separated by the electric field established in the photoelectric conversion layer 142 to form electric current.

The back conductive layer 143 is disposed on the photoelectric conversion layer 142, and may also function as a mirror. In some examples, the back conductive layer 240 may include silver, aluminum, copper, chromium or nickel. Both the back conductive layer 143 and the transparent conductive layer 141 are capable of transmitting the electric current generated by the photoelectric conversion layer 142 to an external loading device (not shown). The back conductive layer 143 may also reflect light and function as a mirror. When light reaches on the surface of the back conductive layer 143 through the photoelectric conversion layer 142, the back conductive layer 143 may reflect the light back to the photoelectric conversion layer 142.

The light emitted from the luminescent member 130 may be reflected between the back conductive layer 143 and the optical layer 120. When the light emitted from the luminescent member 130 is transmitted through the photoelectric conversion layer 142, a portion of the light may be absorbed and thus generate electron-hole pairs. However, a portion of the light may directly pass through the photoelectric conversion layer 142 without generating electron-hole pairs. The light that directly passes through the photoelectric conversion layer 142 can be reflected back into the photoelectric conversion layer 14 by the back conductive layer 143. Further, the light that is reflected from the back conductive layer 143 but still pass through the photoelectric conversion layer 142 without being absorbed, can be reflected by the optical layer 120 due to the reflective characteristic of the optical layer 120 described hereinbefore. Therefore, the light that transmits into the solar cell 100 can be trapped therein and is subsequently converted into electricity. As a result, the efficiency of the solar cell is dramatically increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar cell, comprising:
a transparent substrate;
an optical layer disposed on the transparent substrate, wherein the optical layer reflects light having a wavelength in the range between about 500 nm to about 730 nm, and transmits light having a wavelength in the range between about 300 nm to about 600 nm;
a luminescent member disposed on the optical layer, wherein the luminescent member is operable to emit a light having a wavelength in the range of about 500 nm to about 730 nm; and
a photovoltaic device disposed on the luminescent member.

2. The solar cell according to claim 1, wherein the photovoltaic device comprises:
a transparent conductive layer disposed on the luminescent member;
a photoelectric conversion layer disposed on the transparent conductive layer; and
a back conductive layer disposed on the photoelectric conversion layer.

3. The solar cell according to claim 2, wherein the transparent conductive layer comprises at least one material selected from the group consisting of zinc oxide (ZnO), fluorine doped tin dioxide (SnO₂:F), and Indium tin oxide (ITO).

4. The solar cell according to claim 2, wherein the photoelectric conversion layer comprises amorphous silicon.

5. The solar cell according to claim 2, wherein the back conductive layer comprises at least one material selected from the group consisting of silver, aluminum, copper, chromium and nickel.

6. The solar cell according to claim 1, wherein the optical layer comprises a plurality of first layers and a plurality of second layers, wherein each of the first and second layers are alternately arranged.

7. The solar cell according to claim 6, wherein the first and the second layers respectively have a first refractive index and a second refractive index, and the first refractive index is larger than the second refractive index.

8. The solar cell according to claim 6, wherein the first layer is made of silica and the second layer is made of titanium dioxide.

9. The solar cell according to claim 1, wherein more than 90% of the light having wavelengths in the range of about 500 nm to about 730 nm is reflected by the optical layer; and more than 90% of the light having wavelengths in the range of about 300 nm to about 600 nm is transmitted through the optical layer.

10. The solar cell according to claim 1, wherein the luminescent member comprises a luminescent material having a maximal spectral intensity in the range of about 500 nm to about 700 nm.

11. The solar cell according to claim 10, wherein the luminescent material is selected from the group consisting of 4-(dicyanomethylene)-2-t-butyl-6-(1,1,7,7-tetramethyljulolidyl-9-enyl)-4H-pyran (DCJTB), oxazine-4-perchlorate, 3-phenyl-fluoranthene, GF ORANGE-RED™, GF CLEAR™, FLUOROL 555™, LDS 730™, LDS 750™, BASF 241™ and BASF 339™.

12. The solar cell according to claim 1, wherein the luminescent member comprises a matrix and a luminescent material dispersed therein.

13. The solar cell according to claim 12, wherein the matrix comprises tris(8-hydroxyquinoline) aluminum.

14. The solar cell according to claim 12, wherein the luminescent material is selected from the group consisting of 4-(dicyanomethylene)-2-t-butyl-6-(1,1,7,7-tetramethyljulolidyl-9-enyl)-4H-pyran (DCJTB), oxazine-4-perchlorate, 3-phenyl-fluoranthene, GF ORANGE-RED™, GF CLEAR™, FLUOROL 555™, LDS 730™, LDS 750™, BASF 241™ and BASF 339™.
